(19) United States
(12) Patent Application Publication
(10) Pub. No.: US 2008/0304346 A1
(43) Pub. Date: Dec. 11, 2008

(54) Apparatus and method reducing aging in a data storage device

(76) Inventors: Novat Nintunze, Portland, OR (US); Giao Pham, Austin, TX (US)

Correspondence Address: LAW OFFICE OF DONALD D. MONDUL;c/o INTELLEVATE, P.O. BOX 52050, MINNEAPOLIS, MN, 55402, US

(21) Appl. No.: 11/810,730

(22) Filed: Jun. 7, 2007

(51) Int. Cl. G11C 7/00

(52) U.S. Cl. 365/203

(57) ABSTRACT

An apparatus for reducing aging of at least one transistor device employed in a read path for a data storage device may include: a signal unit coupled with the at least one transistor device and coupled with the data storage device. The signal unit may be coupled for receiving an input signal from the data storage device related with operation of the data storage device. The signal unit may provide a first signal to the at least one transistor device when the input signal is in a first state. The signal unit may provide a second signal to the at least one transistor device when the input signal is in a second state. The first signal may be a variable signal.

### BACKGROUND

Negative bias temperature instability (NBTI) is a phenomenon that may lead to device aging. NBTI may be a critical reliability concern in nanometer range circuits and systems such as, by way of example and not by way of limitation, microprocessors. P-devices may be the most vulnerable when they are stressed for a significant period of time. Such a stressful situation may be prevalent in read paths of memory circuits such as, by way of example and not by way of limitation, register files, ROM (Read Only Memory), PLA (Programmable Logic Array), and cache subarrays. A P-type transistor device may typically effect the precharging of a local bitline (LBL) in read paths of a memory device. Such a LBL precharging device may be in an “ON” orientation most of the time the memory device operates. A related P-type transistor device may be employed in such a memory device or data storage device for keeping a precharged node of the LBL at a predetermined charge level. Such a related P-type transistor device may be referred to as a local charge keeper or a LBL charge keeper. Read paths for storage devices may also include a global bit line (GBL) and another P-type transistor device may be used for keeping a precharged node of the GBL at a predetermined charge level. Such an other P-type transistor device may be referred to as a global charge keeper or a GBL charge keeper.

### BRIEF DESCRIPTION OF THE DRAWINGS

The subject matter of the description is particularly pointed out and distinctly claimed in the concluding portion of the specification. The description, however, both as to organization and method of operation, together with objects, features, and advantages thereof, may best be understood by reference to the following detailed description when read with the accompanying drawings in which:

FIG. 1 is a schematic diagram illustrating a generalized representation of an embodiment of the invention.

FIG. 2 is a schematic diagram illustrating a second embodiment of the invention.

FIG. 3 is a schematic diagram illustrating a third embodiment of the invention.

FIG. 4 is a flow chart illustrating an embodiment of the method of the invention.

It will be appreciated that for simplicity and clarity of illustration, elements illustrated in the figures have not necessarily been drawn to scale. For example, the dimensions of some of the elements may be exaggerated relative to other elements for clarity. Further, where considered appropriate, reference numerals may be repeated among the various figures to indicate corresponding or analogous elements.

### DETAILED DESCRIPTION

In the following detailed description, numerous specific details may be set forth in order to provide a thorough understanding of the description. However, it may be understood by those skilled in the art that embodiments of the present invention may be practiced without these specific details. In other instances, well-known methods, procedures, components and circuits may not have been described in detail so as not to obscure the present description.

Some portions of the detailed description that follows may be presented in terms of algorithms and symbolic representations of operations on data bits or binary digital signals within a computer memory. These algorithmic descriptions and representations may be the techniques used by those skilled in the data processing arts to convey the substance of their work to others skilled in the art.

An algorithm is here, and generally, considered to be a self-consistent sequence of acts or operations leading to a desired result. These include physical manipulations of physical quantities. Usually, though not necessarily, these quantities may take the form of electrical or magnetic signals capable of being stored, transferred, combined, compared, and otherwise manipulated. It may prove convenient at times, principally for reasons of common usage, to refer to these signals as bits, values, elements, symbols, characters, terms, numbers or the like. It may be understood, however, that all of these and similar terms may be associated with the appropriate physical quantities and are merely convenient labels applied to these quantities.

Unless specifically stated otherwise, as apparent from the following discussions, it is appreciated that throughout the specification discussions utilizing terms such as “processing,” “computing,” “calculating,” “determining,” or the like, refer to the action or processes of a computer or computing system, or similar electronic computing device, that manipulate or transform data represented as physical, such as electronic, quantities within the computing system's registers or memories into other data similarly represented as physical quantities within the computing system's memories, registers or other such information storage, transmission or display devices.

Embodiments of the present invention may include apparatuses for performing the operations herein. An apparatus may be specially constructed for the desired purposes, or it may comprise a general purpose computing device selectively activated or reconfigured by a program stored in the device. Such a program may be stored on a storage medium, such as, but not limited to, any type of disk including floppy disks, optical disks, compact disc read only memories (CD-ROMs), magnetic-optical disks, read-only memories (ROMs), random access memories (RAMs), electrically programmable read-only memories (EPROMs), electrically erasable and programmable read only memories (EEPROMs), magnetic or optical cards, or any other type of media suitable for storing electronic instructions, and capable of being coupled to a system bus for a computing device.

The processes and displays presented herein are not inherently related to any particular computing device or other apparatus. Various general purpose systems may be used with programs in accordance with the teachings herein, or it may prove convenient to construct a more specialized apparatus to perform the desired method. The desired structure for a variety of these systems will appear from the description below. In addition, embodiments of the present invention are not described with reference to any particular programming language. It will be appreciated that a variety of programming languages may be used to implement the teachings of the invention as described herein. In addition, it should be understood that operations, capabilities, and features described herein may be implemented with any combination of hardware (discrete or integrated circuits) and software.

Use of the terms “coupled” and “connected”, along with their derivatives, may be used. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, or that the two or more elements co-operate or interact with each other (e.g., as in a cause and effect relationship).

It should be understood that embodiments of the present invention may be used in a variety of applications. Although the present invention is not limited in this respect, the devices disclosed herein may be used in many apparatuses such as in the transmitters and receivers of a radio system, computer systems and other systems employing electronic or digital memory

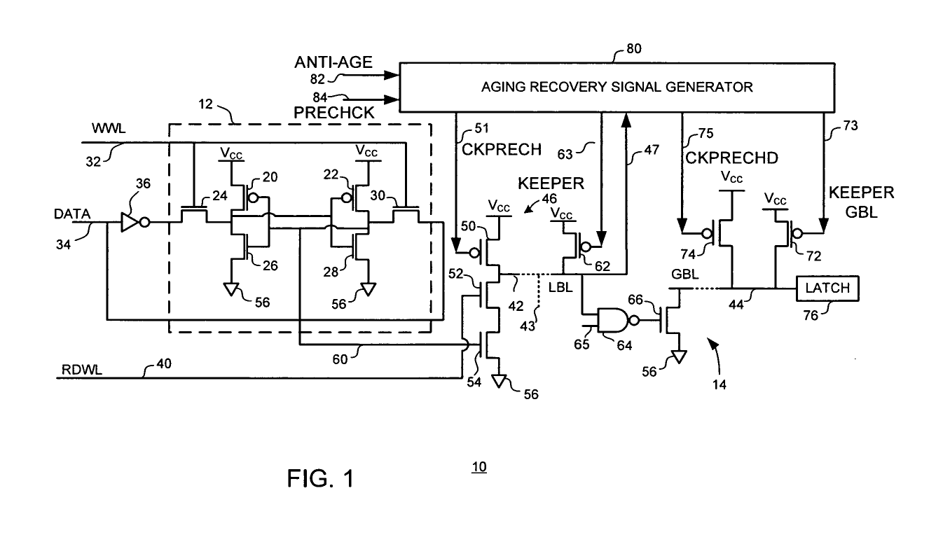

FIG. 1 is a schematic diagram illustrating a generalized representation of an embodiment of the invention. In FIG. 1, a data storage device 10 may include a memory unit 12 coupled with a read path 14. Memory unit 12 may include a pair of P-type transistor devices 20, 22 coupled with N-type transistor devices 24, 26, 28, 30. Memory unit 12 is illustrated in FIG. 1 in a representative orientation commonly referred to as a 6T SRAM (6-Transistor Static Random Access Memory). Embodiments of the invention may be employed using other configurations of memory units, as may be understood by those skilled in the art of memory device design.

A Write Word Line (WWL) 32 coupled for gating N-type transistor devices 24, 30 may cooperate with data presented at a data line 34 coupled to store data presented at data line 34 in memory unit 12. Data line 34 may be coupled with N-type transistor device 24 via an inverter unit 36, so DATA on data line 34 may be presented to N-type transistor device 30 and D̅A̅T̅A̅ (NOT DATA) may be presented to N-type transistor device 24. Contents or data stored in memory unit 12 may be read or recovered from memory unit 12 by read path 14 in response to a signal presented on a Read Word Line (RDWL) 40.

Read path 14 may include a local bit line (LBL) 42 and a global bit line (GBL) 44. A Clocked Precharge (CKPRECH) unit 46 may be coupled with a supply voltage V_{CC}. CKPRECH unit 46 may include a P-type transistor device 50 coupled between supply voltage V_{CC} and LBL 42. An N-type transistor device 52 and an N-type transistor device 54 may be coupled in series between LBL 42 and a ground locus 56. N-type transistor device 52 may be gated by READ signals on RDWL 40. N-type transistor device 54 may be gated by output signals from memory unit 12 on an output line 60. In a device of the sort illustrated in FIG. 1, P-type transistor device 50 may have been gated by a Pre-Charge Clock signal PRECHCK. In the embodiment of the invention illustrated in FIG. 1, P-type transistor device 50 may be gated by a gating signal presented on a gating line 51 from an aging recovery signal generator unit 80. P-type transistor device 50, N-type transistor device 52 and N-type transistor device 54 may cooperate to keep LBL 42 at a predetermined charge level when P-type transistor device 50 may be gated and at least one of N-type transistor devices 52, 54 may be not gated. When N-type transistor devices 52, 54 may be gated, a signal presented on a gating line 51 from aging recovery signal generator unit 80 may be substantially less than or below the gating voltage of P-type transistor device 50 so that P-type transistor device 50 may be not gated, and LBL 42 may experience a charge substantially equal with charge at ground locus 56.

A P-type keeper transistor device 62 may be coupled between a supply voltage V_{CC} and LBL 42. In the embodiment of the invention illustrated in FIG. 1, P-type transistor device 62 may be gated by a gating signal presented on a gating line 63 from aging recovery aging recovery signal generator unit 80. Keeper transistor device 62 may operate to keep LBL 42 at a predetermined charge level when keeper transistor device 62 may be gated. LBL 42 may be coupled with aging recovery signal generator unit 80, as indicated by a line 47, in order to inform aging recovery signal generator unit 80 as to the state of LBL 42.

LBL 42 may also be coupled with global bit line (GBL) 44 via a logic device 64. Logic device 64 operates on a signal from LBL 42 and another logical signal provided at an input locus 65 to control charge on GBL 44 by selectively gating a N-type transistor device 66. N-type transistor device 66 may couple GBL 44 with ground locus 56 when gated and may substantially isolate GBL 44 from ground locus 56 when not gated.

A P-type keeper transistor device 72 may be coupled between a supply voltage V_{CC} and GBL 44. In the embodiment of the invention illustrated in FIG. 1, P-type transistor device 72 may be gated by a gating signal presented on a gating line 73 from aging recovery signal generator unit 80. Keeper transistor device 72 may operate to keep GBL 44 at a predetermined charge level when keeper transistor device 72 may be gated. GBL 44 may be coupled with a latch unit 76.

A second Clocked Precharge (CKPRECHD) P-type transistor device 74 may be coupled between a supply voltage V_{CC} and GBL 44. In the embodiment of the invention illustrated in FIG. 1, P-type transistor device 74 may be gated by a gating signal presented on a gating line 75 from aging recovery signal generator unit 80. P-type transistor device 74 may keep a charge level on GBL 44 when P-type transistor device 74 may be gated.

Aging recovery signal generator unit 80 may receive a substantially steady-state ANTI-AGE signal at an input locus 82 and may receive a precharge clock signal (PRECHCK) signal at an input locus 84. PRECHCK signal may be related with operation of data storage device 10. By way of example and not by way of limitation, PRECHCK signal may be employed to precharge at least one of LBL 42 and GBL 44 prior to each read operation involving memory unit 12. Aging recovery signal generator unit 80 may employ signals ANTI-AGE, PRECHCK to generate a variable output signal to gates of P-type transistor devices 50, 62, 72, 74 when signal PRECHCK is in a first state, and to generate another output signal to gates of P-type transistors 50, 62, 72, 74 when signal PRECHCK is in a second state. The variable output signal may vary between a high value above the gating voltage of P-type transistors 50, 62, 72, 74 and a low value below the gating voltage of P-type transistors 50, 62, 72, 74.

Using such a read-operation related signal as signal PRECHCK may ensure that aging recovery signal generator unit 80 only operates to vary voltages provided to transistor devices 50, 62, 72, 74 when a read operation is not taking place. Such an arrangement may be important to provide an anti-aging effect by aging recovery unit 80 without interfering with operation of data storage device 10.

One skilled in the art of memory device design may understand that data storage device 10 may include more than one memory unit 12, each with associated LBL 42 and GBL 44 and associated precharge and other conditioning supporting transistor devices 50, 52, 54, 62, 72, 74. Such a construction, indicated by dotted line 43 depending from LBL 42, may permit employing one aging recovery signal generator unit 80 for all memory units 12, may permit employing a respective aging recovery signal generator unit 80 for each respective memory unit 12 or may permit employing a respective aging recovery signal generator unit 80 for various sub-groups of memory units 12.

It is known that devices that engage in switching may age less than devices that are in an ON or conductive state for a long time. Further, it is known that devices that engage in switching may exhibit aging recovery. It is for the purpose of taking advantage of this knowledge that aging recovery signal generator unit 80 may be employed to effect toggling of relevant signals in a memory device when not reading data from the memory device.

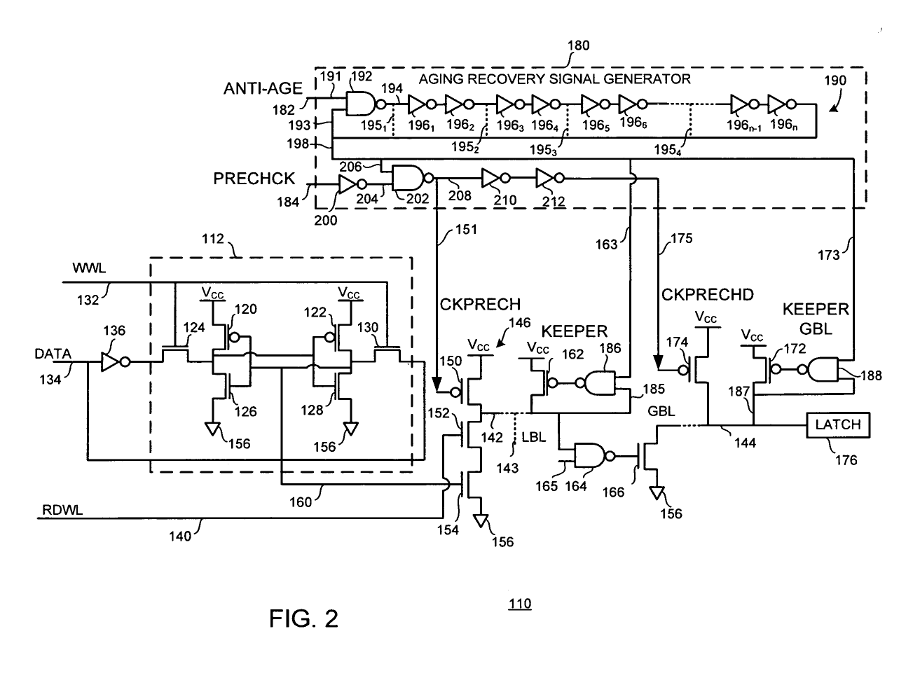

FIG. 2 is a schematic diagram illustrating a second embodiment of the invention. In FIG. 2, a data storage device 110 may include a memory unit 112 coupled with a read path 114. Memory unit 112 may include a pair of P-type transistor devices 120, 122 coupled with N-type transistor devices 124, 126, 128, 130. Memory unit 112 is illustrated in FIG. 2 in a representative orientation commonly referred to as a 6T SRAM (6-Transistor Static Random Access Memory). Embodiments of the invention may be employed using other configurations of memory units, as may be understood by those skilled in the art of memory device design.

A Write Word Line (WWL) 132 coupled for gating N-type transistor devices 124, 130 may cooperate with data presented at a data line 134 coupled to store data presented at data line 134 in memory unit 112. Data line 134 may be coupled with N-type transistor device 124 via an inverter unit 136 to generate D̅A̅T̅A̅ (NOT DATA), so DATA on data line 134 may be presented to N-type transistor device 130 and D̅A̅T̅A̅ may be presented to N-type transistor device 124. Contents or data stored in memory unit 112 may be read or recovered from memory unit 112 by read path 114 in response to a signal presented on a Read Word Line (RDWL) 140.

Read path 114 may include a local bit line (LBL) 142 and a global bit line (GBL) 144. A Clocked Precharge (CKPRECH) unit 146 may be coupled with a supply voltage V_{CC}. CKPRECH unit 146 may include a P-type transistor device 150 coupled between supply voltage V_{CC} and LBL 142. An N-type transistor device 152 and an N-type transistor device 154 may be coupled in series between LBL 142 and a ground locus 156. N-type transistor device 152 may be gated by READ signals on RDWL 140. N-type transistor device 154 may be gated by output signals from memory unit 112 on an output line 160. In a prior art device of the sort illustrated in FIG. 1, P-type transistor device 150 may have been gated by a Pre-Charge Clock signal PRECHCK.

In the embodiment of the invention illustrated in FIG. 2, P-type transistor device 150 may be gated by a gating signal presented on a gating line 151 from an aging recovery signal generator unit 180. P-type transistor device 150, N-type transistor device 152 and N-type transistor device 154 may cooperate to keep LBL 142 at a predetermined charge level when P-type transistor device 150 may be gated and at least one of N-type transistor devices 152, 154 may be not gated. When N-type transistor devices 152, 154 may be gated, and P-type transistor device 150 may be not gated, LBL 142 may experience a charge substantially equal with charge at ground locus 156.

A P-type keeper transistor device 162 may be coupled between a supply voltage V_{CC} and LBL 142. In the embodiment of the invention illustrated in FIG. 2, P-type transistor device 162 may be gated by a gating signal presented on a gating line 163 from aging recovery signal generator unit 180. Keeper transistor device 162 may operate to keep LBL 142 at a predetermined charge level when keeper transistor device 162 may be gated.

LBL 142 may also be coupled with global bit line (GBL) 144 via a logic device 164. Logic device 164 operates on a signal from LBL 142 and another logical signal provided at an input locus 165 to control charge on GBL 144 by selectively gating a N-type transistor device 166. N-type transistor device 166 may couple GBL 144 with ground locus 156 when gated and may substantially isolate GBL 144 from ground locus 156 when not gated.

A P-type keeper transistor device 172 may be coupled between a supply voltage V_{CC} and GBL 144. In the embodiment of the invention illustrated in FIG. 2, P-type transistor device 172 may be gated by a gating signal presented on a gating line 173 from aging recovery signal generator unit 180. Keeper transistor device 172 may operate to keep GBL 144 at a predetermined charge level when keeper transistor device 172 may be gated. GBL 144 may be coupled with a latch unit 176.

A second Clocked Precharge (CKPRECHD) P-type transistor device 174 may be coupled between a supply voltage V_{CC} and GBL 144. In the embodiment of the invention illustrated in FIG. 2, P-type transistor device 174 may be gated by a gating signal presented on a gating line 175 from aging recovery signal generator unit 180. P-type transistor device 174 may keep a charge level on GBL 144 when P-type transistor device 174 may be gated.

Aging recovery signal generator unit 180 may receive a substantially steady-state ANTI-AGE signal at an input locus 182 and may receive a precharge clock signal (PRECHCK) signal at an input locus 184. PRECHCK signal may be related with operation of data storage device 110. By way of example and not by way of limitation, PRECHCK signal may be employed to precharge at least one of LBL 142 and GBL 144 prior to each read operation involving memory unit 112. Aging recovery signal generator unit 180 may employ signals ANTI-AGE, PRECHCK to generate a variable output signal to gates of P-type transistor devices 150, 162, 172, 174 when signal PRECHCK is in a first state, and to generate another output signal to gates of P-type transistors 150, 162, 172, 174 when signal PRECHCK is in a second state. The variable output signal may vary between a high value above the gating threshold voltage of P-type transistors 150, 162, 172, 174 and a low value below the gating threshold voltage of P-type transistors 150, 162, 172, 174.

Aging recovery signal generator unit 180 may be configured as a ring oscillator unit 190 with a programmable duty cycle. Ring oscillator 190 may receive ANTI-AGE signal at input locus 182 as an input signal to a first input locus 191 for NAND gate 192. An output 194 of NAND gate 192 may be provided to serially coupled inverter units 196₁, 196₂, 196₃, 196₄, 196₅, 196₆, 196ₙ₋₁, 196ₙ. An output line 198 from inverter unit 196ₙ may be provided to a second input locus 193 to NAND gate 192. Programmability for ring oscillator 190 may be provided by coupling second input locus 193 with different junctures among inverter devices 196n, as indicated by dotted lines 195₁, 195₂, 195₃, 195₄. Choosing different connection loci 195₁, 195₂, 195₃, 195₄ incorporates a greater or lesser number of device delays imparted by inverter units 196ₙ, thereby altering the period of oscillations for signals presented as oscillator output signals at an oscillator output locus 198.

The indicator “n” is employed to signify that there can be any number of inverter units in oscillator 190. The inclusion of eight inverter units in FIG. 2 is illustrative only and does not constitute any limitation regarding the number of inverter units that may be included in the oscillator of embodiments of the present invention.

If precharge clock signal CKPRECH presented by aging recovery signal generator unit 180 on line 151 and keeper signal KEEPER presented by aging recovery signal generator unit 180 on line 163 remain low for a long time, as may occur by way of example and not by way of limitation in arrays that are infrequently read, a signal may be provided by signal monitoring logic (not shown in FIG. 2) to trigger toggling of those gate signals CKPRECH, KEEPER. Maintaining gate signals unchanged for a long period of time is a source of stress for P-type transistor devices. By toggling the stressing gate signal some aging recovery can take place. Signal PRECHCK may be toggled so that signal PRECHCK is applied to an inverter device 200. A NAND gate 202 receives an input signal P̅R̅E̅C̅H̅C̅K̅ (NOT PRECHCK) at a first input locus 204 and receives an oscillating output signal from oscillator output locus 198 at a second input locus 206. Output signals at an output 208 of NAND gate 202 may be presented, therefore, only when input signals at both input loci 204, 206 are a “1” value. Because of the presence of inverter device 200 an input signal at input locus 204 can only be a “1” value when signal PRECHCK is a “0” value. That is to say, signals may be presented at lines 151, 175 only when data storage device 110 is not reading memory unit 112. Signals on line 175 may be delayed with respect to signals on line 151 because of two inverter devices 210, 212 coupled in series with output locus 208.

Output signals from oscillator 190 are also presented from oscillator output locus 198 to lines 163, 173. Signals on line 163 may be presented as one input to a NAND gate 186. The other input to NAND gate 186 may be provided from LBL 142. In such a configuration, signals provided from NAND gate 186 may only be low (and therefore gating P-type transistor device 162) when both of oscillator output locus 198 and LBL 142 are a “1” value.

Signals on line 173 may be presented as one input to a NAND gate 188. The other input to NAND gate 188 may be provided from GBL 144. Signals provided from NAND gate 188 may only be low (and therefore gating P-type transistor device 172) when both of oscillator output locus 198 and GBL 144 are a “1” value. The period of oscillation for oscillator 190 may be set experimentally, and programming can be effected using software or fuses.

ANTI-AGE input signal provided to aging recovery signal generator unit 180 may be similar to or derived from a cache-content inversion signal, may be the complement of the read signal on RDWL 140 or may involve a combination of signals otherwise available in data storage device 110, such as a burn-in signal.

Using such a read-operation related signal as signal PRECHCK may ensure that aging recovery signal generator unit 180 only operates to vary voltages provided to transistor devices 150, 162, 172, 174 when a read operation is not taking place. Such an arrangement may be important to provide an anti-aging effect by aging recovery signal generator unit 180 without interfering with operation of data storage device 110.

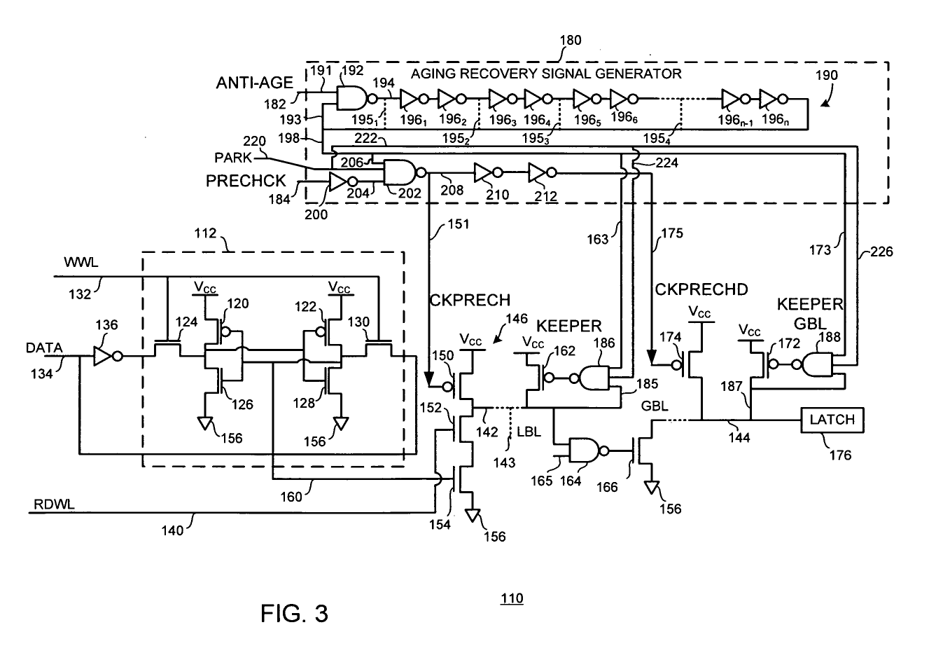

FIG. 3 is a schematic diagram illustrating a third embodiment of the invention. The third embodiment of the invention illustrated in FIG. 3 is substantially similar to data storage device 110 illustrated in FIG. 2 with an addition of a “Park” or “Sleep” control capability. Because of the extensive similarity between FIGS. 2 and 3, in order to avoid prolixity only new material in FIG. 3 additional to the disclosure of FIG. 2 will be described.

NAND gate 202 in aging recovery signal generator unit 180 may be configured to receive an additional signal PARK at an input locus 220. The PARK signal may be regarded as a “sleep” control signal that may override operation of data storage device 110. Presence of the PARK signal as an input to NAND gate 202 means that signals appearing at output locus 208 may only have a “0” value when all three inputs to NAND gate 202 have a “1” value. Said another way, the PARK signal can control whether output signals from NAND gate 202 are high, and therefore can remove stress from P-type transistor devices 150, 174, regardless of the state of the other two input signals to NAND gate 202.

PARK signal may also be provided to a signal line 222. Signal line 222 may be coupled with a line 224 applied to a third input locus for NAND gate 186. Presence of the PARK signal as an input to NAND gate 186 means that signals provided from NAND gate 186 may only have a “0” value when all three inputs to NAND gate 186 have a “1” value. Said another way, the PARK signal can control whether output signals from NAND gate 186 are high, and therefore can remove stress from P-type transistor device 162, regardless of the state of the other two input signals to NAND gate 186.

Signal line 222 may be coupled with a line 226 applied to a third input locus for NAND gate 188. Presence of the PARK signal as an input to NAND gate 188 means that signals provided from NAND gate 188 may only have a “0” value when all three inputs to NAND gate 188 have a “1” value. Said another way, the PARK signal can control whether output signals from NAND gate 188 are high, and therefore can remove stress from P-type transistor device 172, regardless of the state of the other two input signals to NAND gate 188.

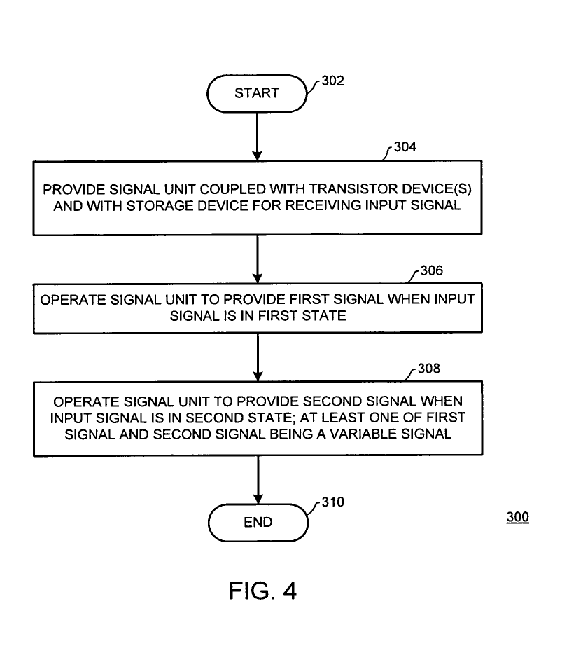

FIG. 4 is a flow chart illustrating an embodiment of the method of the invention. In FIG. 4, a method 300 reducing aging of at least one transistor device employed in a read path for a data storage device begins at a START locus 302. Method 300 continues with providing a signal generating unit coupled with the at least one transistor device and coupled with the data storage device for receiving an input signal from the data storage device related with operation of the data storage device, as indicated by a block 304.

Method 300 continues with operating the signal generating unit to provide a first signal to the at least one transistor device when the input signal is in a first state, as indicated by a block 306.

Method 300 continues by operating the signal generating unit to provide a second signal to the at least one transistor device when the input signal is in a second state, as indicated by a block 308. At least one of the first signal and the second signal is a variable signal. Method 300 terminates at an END locus 310.

Embodiments of the invention may be advantageous by reducing stress in devices in a circuit that are critically affected by negative bias temperature instability (NBTI) when the circuit is not active. Reduced stress has been associated with aging recovery. Embodiments of the invention may be programmed in-the-field using software or fuse manipulation thereby permitting straightforward setting of the frequency of oscillation of the stress signal. Embodiments of the invention permit aging retardation without the need to “wake” the circuitry from a “sleep” or other dormant condition. The signal employed for effecting oscillating age or stress reduction signals may be derived from other signals already present in a circuit thereby avoiding having to generate a special signal for implementing embodiments of the invention. By way of example and not by way of limitation, some already-existing signals in a data storage device or circuit that may be amenable for use with embodiments of the invention may include a precharge clock buffer signal, a read word line signal or a burn-in signal. Employing the invention for each respective portion of a multi-portion device may provide a capability for turning off or reducing stress to critical devices when arrays containing those devices are not actively accessed.

While certain features of embodiments of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. An apparatus comprising: a signal unit coupled with at least one transistor device in read path of a data storage device and coupled with said data storage device; said signal generating unit being coupled to receive an input signal from said data storage device; said input signal being related with said data storage device being operated to effect a predetermined function; said signal generating unit being coupled to provide a first signal to said at least one transistor device when said input signal is in a first state to indicate said data storage device is being operated to effect said predetermined function; said signal generating unit being configured to provide a second signal to said at least one transistor device when said input signal is in a second state to indicate said data storage device is not being operated to effect said predetermined function; said first signal being configured to vary in amplitude between an upper signal level above a gating voltage of said at least one transistor device and a lower signal level below said gating voltage of said at least one transistor device.

2. An apparatus as recited in claim 1 wherein said read path is configured to include a local bit line, and wherein said at least one transistor device is configured to include a local charge keeper transistor coupled with said local bit line.

3. An apparatus as recited in claim 1 wherein said read path is configured to include a global bit line, and wherein said at least one transistor device is configured to include a global charge keeper transistor coupled with said global bit line.

4. An apparatus as recited in claim 1 wherein said read path is configured to include a read word line, and wherein said at least one transistor device is configured to include a clock precharge control switching transistor coupled with said read word line.

5. An apparatus as recited in claim 2 wherein said read path is configured to include a global bit line, and wherein said at least one transistor device is configured to include a global charge keeper transistor coupled with said global bit line.

6. An apparatus as recited in claim 2 wherein said read path is configured to include a read word line, and wherein said at least one transistor device is configured to include a clock precharge control switching transistor coupled with said read word line.

7. An apparatus as recited in claim 1 wherein said second signal is substantially below said gating voltage of said at least one transistor device.

8. An apparatus as recited in claim 2 wherein said second signal is substantially below said gating voltage of said at least one transistor device.

9. A method comprising:
(a) operating a signal generating unit to provide a first signal to at least one transistor device in a read path of a data storage device when an input signal is in a first state; said signal generating unit being coupled with said at least one transistor device and coupled with said data storage device for receiving said input signal from said data storage device; said input signal being in said first state to indicate said data storage device is being operated to effect a predetermined function; said first signal being configured to vary in amplitude generally between a high limit and a low limit; said high limit being greater than a gating voltage of said at least one transistor device; said low limit being less than said gating voltage of said at least one transistor device; and
(b) operating said signal generating unit to provide a second signal to said at least one transistor device when said input signal is in a second state to indicate said data storage device is not being operated to effect a predetermined function.

10. A method as recited in claim 9 wherein said read path is configured to include a local bit line, and wherein said at least one transistor device is configured to include a local charge keeper transistor coupled with said local bit line.

11. A method as recited in claim 9 wherein said read path is configured to include a global bit line, and wherein said at least one transistor device is configured to include a global charge keeper transistor coupled with said global bit line.

12. A method as recited in claim 9 wherein said read path is configured to include a read word line, and wherein said at least one transistor device is configured to include a clock precharge control switching transistor coupled with said read word line.

13. A method as recited in claim 10 wherein said read path is configured to include a global bit line, and wherein said at least one transistor device is configured to include a global charge keeper transistor coupled with said global bit line.

14. A method as recited in claim 10 wherein said read path is configured to include a read word line, and wherein said at least one transistor device is configured to include a clock precharge control switching transistor coupled with said read word line.

15. A method as recited in claim 9 wherein said second signal is substantially below a gating voltage of said at least one transistor device.

16. A method as recited in claim 10 wherein said second signal is substantially below a gating voltage of said at least one transistor device.
